(19) United States
(12) Patent Application Publication
(10) Pub. No.: US 2012/0001891 A1
(43) Pub. Date: Jan. 5, 2012

(54) ACTIVE MATRIX TYPE DISPLAY APPARATUS

(75) Inventor: Shinichi Ishizuka, Saitama (JP)

(73) Assignee: PIONEER CORPORATION, Tokyo (JP)

(21) Appl. No.: 13/229,919

(22) Filed: Sep. 12, 2011

Related U.S. Application Data
(62) Division of application No. 11/914,116, filed on Jan. 30, 2008.

(30) Foreign Application Priority Data
May 11, 2005 (JP) 2005-138592

(51) Int. Cl. G09G 5/00; G09G 3/30

(52) U.S. Cl. 345/212; 345/76

(57) ABSTRACT

A display apparatus includes a capacitor which is provided on each of the pixels and stores the data signal while a first terminal of the capacitor is connected to a control electrode of the driving transistor, an application voltage generating unit which generates an application voltage to a second terminal of the capacitor, and a capacitor voltage adjusting unit which adjusts an application voltage to the second terminal of the capacitor.

### CROSS REFERENCE TO RELATED APPLICATIONS

This application is a divisional of U.S. application Ser. No. 11/914,116 filed on Jan. 30, 2008 which is a National Stage of International Application No. PCT/JP2006/309523 filed on May 2, 2006, claiming priority from Japanese Patent Application No. 2005-138592, filed May 11, 2005, the contents of all of which are incorporated herein by reference in their entirety.

### BACKGROUND OF THE INVENTION

1. Field of the Invention

The invention relates to a display apparatus including an active element that drives a light-emitting element such as an EL (electroluminescent) element or an LED (light emitting diode), and particularly, to a display apparatus including a thin film transistor (TFT) as an active element.

2. Description of the Related Art

TFT has been widely used as an active element that drives an active matrix display apparatus such as an organic EL display device or a liquid crystal display device. FIG. 1 illustrates an example of an equivalent circuit of a driving circuit of an organic EL (OEL) element 100 with respect to a pixel PL_{i, j}. Referring to FIG. 1, the equivalent circuit includes two p-channel TFTs 101 and 102 and a capacitor (Cs) 104. A scanning line Ws is connected to a gate of the selection TFT 101, a data line Wd is connected to a source of the selection TFT 101, and a power line Wz for supplying a constant voltage Vdd is connected to a source of the driving TFT 102. A drain of the selection TFT 101 is connected to a gate of the driving TFT 102 and the capacitor 104 is formed between the gate and the source of the driving TFT 102. An anode of the OEL element 100 is connected to a drain of the driving TFT 102 and a cathode of the OEL element 100 is connected to an earth potential (or common potential).

When a selection pulse is applied to the scanning line Ws, the selection TFT 101 serving as a switch is turned on, thereby generating a conducting path between the source and the drain. At this time, data voltage is supplied from the data line Wd through the path between the source and the drain of the selection TFT 101 and is accumulated in the capacitor 104. As the data voltage accumulated in the capacitor 104 is applied between the gate and the source of the driving TFT 102, a drain current Id flows to the OEL element 100 with the voltage Vgs between the gate and the source of the driving TFT 102.

However, it has been known that a gate stress occurs in a TFT using an amorphous silicon (α-Si) or an organic semiconductor. (see, for example, S. J. Zilker, C. Detcheverry, E. Cantalore, and D. M. de Leeuw, “Bias stress in organic thin-film transistors and logic gates”, Applied Physics Letters Vol. 79(8) pp. 1124 to 1126, (Aug. 20, 2001)). The gate stress implies a phenomenon that a gate threshold voltage Vth is shifted when a voltage is continuously applied to a gate. This phenomenon will be described with reference to a p-channel TFT.

FIG. 2 illustrates a shift of a gate threshold voltage Vth due to the gate stress. In case of a p-channel TFT, when a negative gate-source voltage (i.e., Vgs<0) is continuously applied, a Id−Vgs characteristic graph is moved to a negative direction (from a curve 120A to a curve 120B) as shown in FIG. 2 due to the gate stress as the time elapses, such that the gate threshold voltage Vth is shifted from Vth1 to Vth2. In FIG. 2, a positive Vgs (Vgs>0) is shown for ease of understanding.

In the TFT characteristic, when 0V or a positive gate-source voltage Vgs is continuously applied, Vth is return to the initial gate threshold voltage Vth. On the contrary, when a positive Vgs is continuously applied, the gate threshold voltage Vth is shifted to a positive direction as the time elapses. When 0V or negative Vgs is continuously applied, Vth is returned to the initial gate threshold voltage Vth. The amount of shift increases as the absolute value and application period of time of the gate threshold voltage Vth increases. When the TFT having the above-mentioned characteristic is used to drive the organic EL element, the gate threshold voltage Vth is gradually shifted during the display. The shift of the gate threshold voltage causes deterioration of the luminance of the OEL element or malfunction of the TFT.

TFT is mainly made of single crystalline silicon, amorphous silicon, polycrystalline silicon, or low-temperature polycrystalline silicon. In addition, TFT using an organic material as an active layer (hereinafter referred to as organic TFT) recently comes into notice instead of the above-mentioned silicon. Examples of the organic semiconductor material may be low-molecular or high-molecular organic material, such as pentacene, naphthacene or polythiophene material, having relatively high carrier mobility. The organic TFT can be formed on a flexible film substrate, such as plastic, by a relatively low temperature process. Thus, it is possible to easily manufacture a flexible, light, thin display device. In addition, it is possible to form the organic TFT with a relatively low cost by a print process or roll-to-roll process.

The threshold voltage shift remarkably occurs particularly in an amorphous silicon TFT or organic TFT. The threshold voltage shift of the organic TFT is described, for example, S. J. Zilker, C. Detcheverry, E. Cantalore, and D. M. de Leeuw, “Bias stress in organic thin-film transistors and logic gates”, Applied Physics Letters Vol. 79(8) pp. 1124 to 1126, (Aug. 20, 2001).

A driving circuit and method of compensating for the threshold voltage shift of TFT is disclosed in Japanese Patent Application Kokai No. 2002-514320 and No. 2002-351401. The driving circuit and method disclosed in the above-mentioned documents allow the threshold voltage shift of the driving TFT but can constantly control the luminance of the light-emitting element regardless of the threshold voltage shift of the driving TFT. However, since it is not possible to prevent occurrence of the threshold voltage shift, it is not possible to prevent an increase of power consumption due to the threshold voltage shift. In addition, when the threshold voltage of the driving TFT is shifted to exceed its allowable range, it is difficult to compensate for the shift, and a deviation of the luminance or malfunction of the TFT occurs. In addition, since the threshold voltage is shifted in the selection TFT in addition to the driving TFT, malfunction of the selection TFT occurs when the threshold voltage of the selection TFT is shifted to exceed its allowable range. In particular, the threshold voltage shift of an organic TFT or amorphous silicon (α-Si) TFT is larger than that of a low-temperature polysilicon TFT or single crystalline silicon TFT. Thus, there is a problem in that a deviation of the luminance of the light-emitting element or malfunction of the TFT is apt to occur in an active matrix display device using the organic TFT or amorphous silicon TFT.

Further, in order to remove the deviation in the TFT characteristic, a configuration for connection between the source, drain, or capacitor of driving TFT and the scanning line (refer to Japanese Patent Application Kokai No. 2004-170815), and a configuration for connection of TFT for reducing the threshold voltage shift of α-Si transistor (refer to Japanese Patent Application Kokai No. 2005-004174) are disclosed.

However, in the driving circuit and method disclosed in the above-mentioned references, configuration and operation of the circuit is complex and its effect is limited.

### SUMMARY OF THE INVENTION

Accordingly, it is an object of the present invention to provide a display device that improves the characteristic of a transistor, particularly an organic semiconductor transistor, used in an active matrix driving method. In addition, it is an object of the invention to provide an active matrix display device that has high display quality, a low power consumption, and simple circuit configuration and operation so as to solve the deviation of the threshold characteristic of the transistor.

According to an aspect of the present invention, there is provided a display device including an active matrix display panel which has a plurality of pixel portions each having a light-emitting element and a driving transistor for driving the light-emitting element based on a data signal, a scanning driver unit which sequentially scans scanning lines of the display panel, a data driver unit which supplies the data signal to the pixel portions in accordance with the scanning of the scanning driver unit, a capacitor which is provided in each of the pixel portions and stores the data signal while a first terminal of the capacitor is connected to a control electrode of the driving transistor, an application voltage generating unit which generates an application voltage to a second terminal of the capacitor, and a capacitor voltage adjusting unit which adjusts an application voltage to the second terminal.

### BRIEF DESCRIPTION OF THE DRAWINGS

FIG. 1 is a view illustrating an equivalent circuit of a driving circuit for driving a light-emitting element according to the related art;

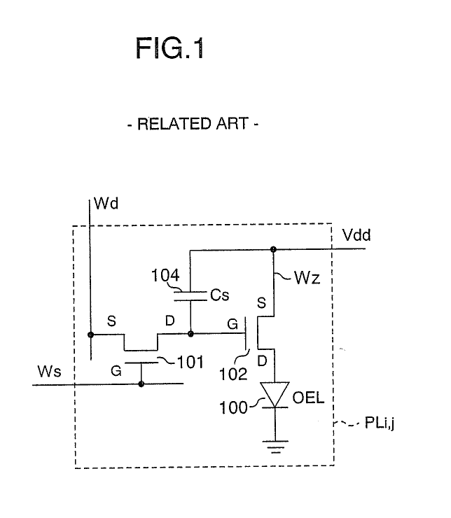

FIG. 2 is a view illustrating a shift of gate threshold voltage Vth due to a gate stress;

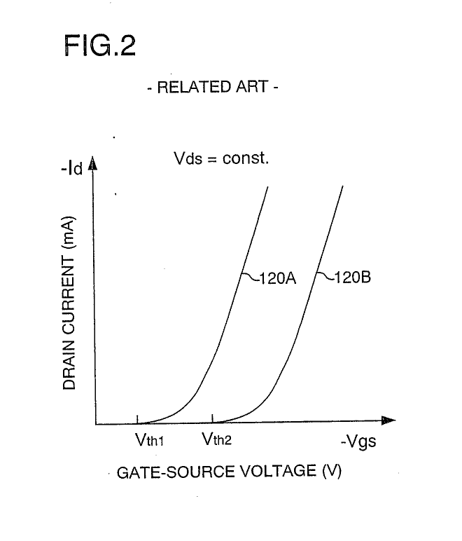

FIG. 3 is a block diagram of a display device using an active matrix display panel according to a first embodiment of the invention;

FIG. 4 is a view illustrating a pixel portion PL_{j, i} related to a data line Xi and a scanning line Yj among a plurality of pixel portions in a display panel;

FIG. 5 is a timing chart illustrating an application timing of scanning pulses applied to scanning lines Y1 to Yn of a display panel and an application timing of a capacitor driving voltage Vc applied to capacitor lines W1 to Wn;

FIG. 6 is a view illustrating an application voltage to a capacitor Cs in each of pixel portions and a capacitor bias voltage, and a gate-source voltage and gate voltage of a driving TFT;

FIG. 7 is a block diagram of a display device using an active matrix display panel according to a second embodiment of the invention;

FIG. 8 is a timing chart illustrating an application timing of scanning pulses applied to scanning lines Y1 to Yn of the display device shown in FIG. 7 and an application timing of a capacitor driving voltage Vc applied to a capacitor line W;

FIG. 9 is a block diagram of a display device using an active matrix display panel according to a third embodiment of the invention;

FIG. 10 illustrates a circuit configuration of pixel portions and PL_{j-1, i} and PL_{j, i} in a display panel of according to the third embodiment of the invention; and

FIG. 11 is a timing chart showing an application timing of scanning pulses applied to scanning lines Yj−1 to Yj of the display device shown in FIG. 9 and an application timing of a capacitor driving voltage Vc applied to capacitors 24 in pixel portions PL_{j-1, i} and PL_{j, i}.

FIG. 12 illustrates a display device having an active matrix display panel according to a fourth embodiment of the present invention.

FIG. 13 illustrates a pixel PL_{j, i} related to a data line Xi and a scanning line Yj of the display panel.

FIG. 14 is a timing chart showing an application timing of scanning pulses applied to the scanning lines Y1 to Yn and an application timing of the driving voltage Vz applied to the light-emitting element driving lines Z1 to Zn.

FIG. 15 shows an application voltage to the j-th scanning line Yj and the voltage change of the driving TFT.

FIG. 16 illustrates a display device having an active matrix display panel according to a fifth embodiment of the present invention.

FIG. 17 is a timing chart showing an application timing of scanning pulses applied to scanning lines Y1 to Yn and an application timing of the driving voltage Vz applied to the light-emitting element driving line Z.

FIG. 18 shows an application voltage to the j-th scanning line Yj and the voltage change of the driving TFT.

FIG. 19 illustrates a timing chart of the modification of the embodiment.

FIG. 20 illustrates a timing chart of the modification of the embodiment.

FIG. 21 illustrates a display device having an active matrix display panel according to a sixth embodiment of the present invention.

FIG. 22 shows a circuit configuration of pixel PL_{j-1, i} and PL_{j, i} in a display panel of the third embodiment.

FIG. 23 shows a timing chart illustrating the voltage applied to the scanning line Yj as well as the voltage applied to the connection line (Zj) (j=1 to n).

FIG. 24 illustrates the scanning voltage applied to the source of the TFT 22 in the pixel portions PL_{j, i} on the scanning line Yj, together with the data voltage to the driving TFT and the source-gate voltage of the driving TFT.

FIG. 25 illustrates a portion of a seventh embodiment of the present invention, specifically, a pixel portion PL_{j, i} related to a data line Xi and a scanning line Yj.

FIG. 26 shows a timing chart illustrating an operation of the switches SW1-SW3, and the voltage change of the capacitor line and the source-gate voltage of the driving TFT.

FIG. 27 shows the configuration of the pixel PL_{j, i} of the modified embodiment of the seventh embodiment.

FIG. 28 shows a timing chart illustrating the changes of the capacitor line voltage and the source-gate voltage of the driving TFT.

### DETAILED DESCRIPTION OF THE INVENTION

Preferred embodiments of the invention will be described in detail with reference to the accompanying drawings. In the drawings, the same elements are denoted by the same reference numerals.

### First Embodiment

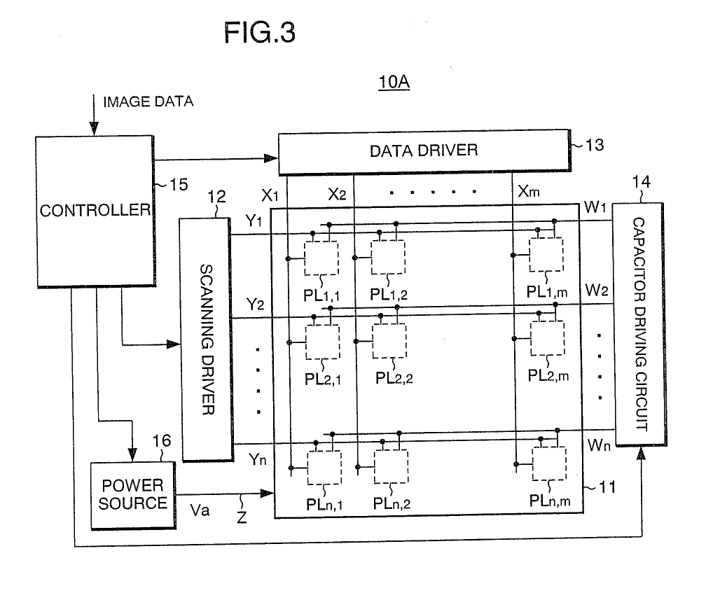

FIG. 3 illustrates a display device 10A having an active matrix display panel according to a first embodiment of the present invention. The display device 10A includes a display panel 11, a scanning driver 12, a data driver 13, a capacitor driving circuit 14, a controller 15, and a power source for driving a light-emitting element (hereinafter, also simply referred to as power source) 16.

The display panel 11 is an active matrix display panel consisting of m×n pixels (m and n are integers equal to or more than 2), and has a plurality of data lines X1 to Xm (Xi: i=1 to m) arranged in parallel, a plurality of scanning lines Y1 to Yn (Yj: j=1 to n) arranged in parallel, and a plurality of pixels or pixel portions PL_{1, 1} to PL_{n, m}. The pixel portions PL_{1, 1} to PL_{n, m} are arranged at intersections between the data lines X1 to Xm and the scanning lines Y1 to Yn, and have the same configuration. The pixel portions PL_{1, 1} to PL_{n, m} are connected to a power line or power source line Z. A light-emitting element driving voltage Va is supplied to the power line Z from the power source 16.

In addition, connection lines (capacitor lines) W1 to Wn are provided to correspond to the scanning lines Y1 to Yn, respectively. As described below, a voltage signal having predetermined amplitude is supplied from the capacitor driving circuit 14 to each of the capacitor lines W1 to Wn in a predetermined timing.

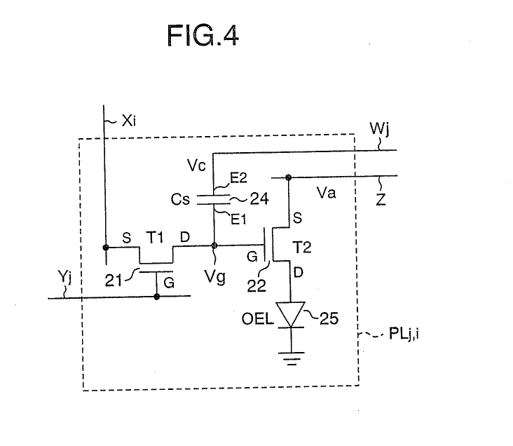

FIG. 4 illustrates a pixel or pixel portion PL_{j, i} related to a data line Xi (i=1, 2, . . . m) and a scanning line Yj (j=1, 2, . . . , n) among a plurality of pixel portions of the display panel 11. In more detail, the pixel portion PL_{j, i} includes two selection and driving TFTs (thin film transistors) 21 and 22, a data holding capacitor Cs 24, and an organic EL (electroluminescent) light-emitting element 25. The two TFTs 21 and 22 will be assumed to be P-channel TFTs.

The gate of the selection TFT (T1) 21 is connected to the scanning line Yj, and the source of the selection TFT 21 is connected to the data line Xi. The drain of the selection TFT 21 is connected to the gate of the driving TFT (T2) 22. The source of the TFT 22 is connected to the power line Z, and a power source voltage (positive voltage Va) is supplied from the power source 16 to the source of the TFT 22. The drain of the TFT 22 is connected to an anode of the EL element 25. A cathode of the EL element 25 is connected to a ground terminal.

In the embodiment, one end (first terminal; electrode E1) of the capacitor Cs 24 is connected to the gate of the driving TFT (and the drain of the selection TFT 21), and the other end (second terminal; electrode E2) is connected to the capacitor driving circuit 14 through the capacitor line Wj. The capacitor driving voltage Vc is supplied from the capacitor driving circuit 14 to the capacitor Cs 24 through the capacitor lines W1 to Wn.

The scanning lines Y1 to Yn of the display panel 11 are connected to the scanning driver 12, and the data lines X1 to Xm are connected to the data driver 13. The controller 15 generates a scanning control signal and a data control signal to drive the display panel 11 in gray scale according to an image signal. The scanning control signal is supplied to the scanning driver 12, and the data control signal is supplied to the data driver 13.

The scanning driver 12 supplies scanning pulses for displaying to the scanning lines Y1 to Yn in a predetermined timing according to the scanning control signal transmitted from the controller 15, thereby performing a line sequential scanning or a-line-at-a-time scanning.

The data driver 13 supplies pixel data signals for individual pixel portions located on scanning lines, to which the scanning pulses are supplied, to pixel portions (selected pixel portions) through the data lines X1 to Xm according to data control signals sent from the controller 15. A pixel data signal having a level which indicates non-emission of the EL element is supplied to a non-light-emitting pixel portion.

The controller 15 controls the display device 10A, i.e., the scanning driver 12, the data driver 13, the capacitor driving circuit 14, and the power source 16 for driving the light-emitting element. As described above, the capacitor driving circuit 14 applies the capacitor driving voltage Vc so as to drive the capacitor 24. That is, the capacitor driving circuit 14 acts under the control of the controller 15 as an application voltage generation unit that generates an application voltage to a second terminal of the capacitor 24, and a capacitor voltage adjusting unit that adjusts an application voltage (capacitor driving voltage Vc) to a second terminal of the capacitor 24.

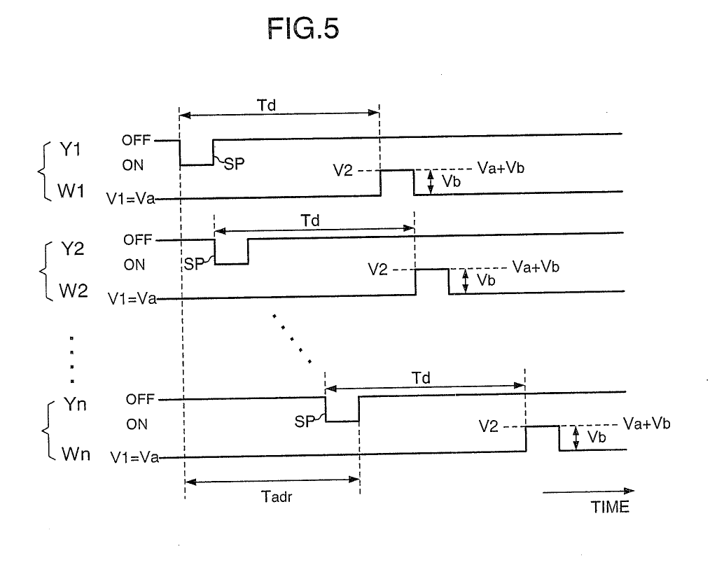

FIG. 5 is a timing chart showing an application timing of scanning pulses applied to scanning lines Y1 to Yn of a display panel 11 and an application timing of a capacitor driving voltage Vc applied to the capacitor lines W1 to Wn.

In each frame of an input image signal, scanning pulses are sequentially applied to the first to n-th scanning lines Y1 to Yn (addressing period: Tadr) so as to perform line sequential scanning or a-line-at-a-time scanning. In more detail, a voltage Va is applied to the capacitor line Wj (j=1 to n) as the capacitor driving voltage Vc=V1 (hereinafter, referred to as first capacitor driving voltage or first voltage) applied to the capacitor Cs 24 when an image is displayed. The capacitor driving voltage V1 applied during a display operation may be a predetermined voltage by which the driving TFT 22 can drive the light-emitting element when a data signal voltage Vdata is applied to a gate of the driving TFT 22. However, the embodiment describes a case where the capacitor driving voltage V1 is equal to the light-emitting element driving voltage Va applied to a source of the driving TFT 22 (i.e., V1=Va>0). A data signal indicating the luminance of each pixel is applied through the data line X1 to Xm to correspond according to line sequential scanning (not shown), and the pixel display control of the display panel 11 is performed.

In the embodiment, an electrode (first electrode) E1 on one side of the capacitor Cs 24 is connected to the gate of the driving TFT 22. The first capacitor driving voltage V1 (=Va) is applied to an electrode (second electrode) E2 on the other side of the capacitor Cs 24.

After a predetermined period of time Td from when a scanning pulse SP is applied to a scanning line Yj (j=1 to n), a capacitor bias voltage Vb, in addition to the first voltage V1, is applied from the capacitor driving circuit 14 to the electrode E2 (second terminal) of the capacitor Cs 24 through the capacitor line Wj (j=1 to n), and the capacitor driving voltage Vc becomes the second voltage V2 (i.e., Vc=V2). In more detail, the capacitor bias voltage Vb is applied as the capacitor driving voltage in addition to the first voltage V1 (=Va), and the voltage V2 (second capacitor driving voltage) of the electrode E2 of the capacitor Cs 24 becomes Vc=V2=Va+Vb.

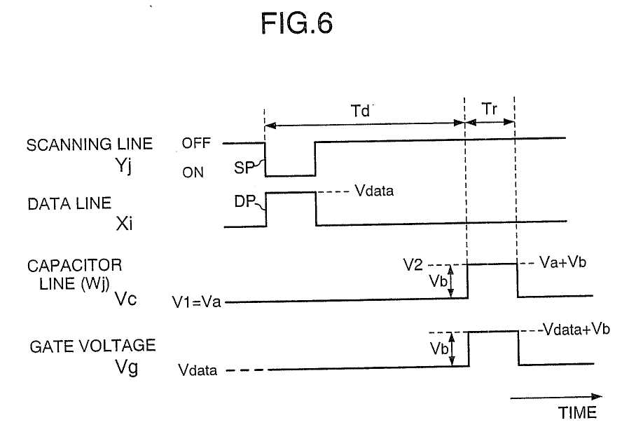

Next, the application voltage and capacitor bias voltage to the capacitor Cs 24 of each pixel portion, and the gate-source voltage and gate voltage of the driving TFT 22 will be described in detail with reference to FIG. 6. In FIG. 6, a j-th scanning line Yj (j=1 to n) will be described. When a scanning pulse SP is applied to the scanning line Yj of the pixel portion PL_{j, i} so as to select the scanning line Yj (scanning line Yj is turned on), the selection TFT 21 is turned on and a pixel data signal pulse DP (data voltage Vdata) is applied from the data driver 13 to the gate of the driving TFT 22 through the selection TFT 21. Since the first voltage V1=Va (>0) is applied as the capacitor driving voltage Vc to the electrode E2 of the capacitor Cs 24, electric charges corresponding to the voltage Vc−Vdata=Va−Vdata are accumulated in the capacitor 24, such that corresponding voltage is held. A drain current due to the gate-source voltage Vgs (=Vdata−Va<0) flows on the driving TFT 22. Thus, the OEL element 25 is driven and emits light according to the pixel data signal (data voltage Vdata).

After a predetermined period (Td) from when the scanning pulse SP is applied to, the capacitor bias voltage Vb (>0) is added to the application voltage to the capacitor line Wj, the capacitor driving voltage Vc becomes Vc=V2=Va+Vb, and the gate voltage Vg of the driving TFT 22 is changed from Vdata to Vdata+Vb. At this time, by setting the gate voltage Vg=Vdata+Vb of the driving TFT 22 to exceed the source voltage Vs=Va of the driving TFT 22 (i.e., Vdata+Vb>Va), a positive reverse bias voltage (Vr=Vdata+Vb−Va>0) of the gate-source voltage of the driving TFT 22 can be applied. Thus, by applying the driving voltage Vc to the electrode E2 of the capacitor Cs 24 so that the gate voltage Vg of the driving TFT 22 exceeds the source voltage Vs of the driving TFT 22, it is possible to apply the positive reverse voltage (Vr>0) between the gate and the source of the driving TFT 22, such that the threshold voltage (Vth) shift of the driving TFT 22 is reduced and the gate stress is reduced.

Further, by setting the gate voltage Vg=Vdata+Vb of the driving TFT 22 to be equal to the source voltage Vs=Va of the driving TFT 22 (i.e., Vdata+Vb=Va), the gate-source voltage can be equal to 0V (Vr=0). Accordingly, it is possible to reduce the threshold voltage (Vth) shift of TFT by setting the gate voltage Vg of the TFT 22 to be equal to the source voltage Vs of the driving TFT 22.

The application period (Tr) of the reverse bias voltage (Vr>0 or Vr=0) may be set in an arbitrary manner.

In the embodiment, since the capacitor bias voltage Vb is applied to each scanning line in addition to the capacitor driving voltage, the reverse bias voltage Vr can be applied to the driving TFT 22 for each scanning line. For example, the OEL element 25 does not emit light during the period when the reverse bias voltage Vr is applied to the driving TFT 22. Thus, when the period Td between the application of the scanning pulse SP and the application of the capacitor bias voltage Vb to the capacitor line Wj is set to be constant for each scanning line, the light-emitting period Td can be equally set for each scanning line. The light-emitting period of time may be controlled to be differently set for each scanning line by setting different light-emitting periods (i.e., Td1, Td2, . . . , Tdn) for each scanning line.

When the light-emitting period is controlled, the application voltage is not limited to the reverse bias voltage Vr. That is, a voltage for preventing the light-emitting element 25 from emitting light may be applied to control the light-emitting period. For example, in order to stop emitting light, the capacitor bias voltage Vb may be applied so that Va>Vdata+Vb>Va−Vth.

Accordingly, it is possible to adjust the luminance of the entire display panel 11 by controlling the light-emitting period of time. Also, sub-field period may be set and gray scale may be controlled by controlling the light-emitting period. For example, the controller 15 determines the light-emitting period Td corresponding to the luminance of the display panel 11 based on an input image signal or the luminance specifying signal of a user to control the application timing of the reverse bias voltage Vr. Meanwhile, when the display control is performed by a sub-field method, a desired sub-field period is determined to control the gray scale.

In addition, while a case where the period Td is larger than the addressing period of each frame (Tadr<Td) has been shown in FIG. 5, the period Td may be set to be shorter than the addressing period (Tadr>Td or Tadr=Td). Also, the application period Tr of the reverse bias voltage (Vr>0) may be arbitrary set with respect to each scanning line.

### Second Embodiment

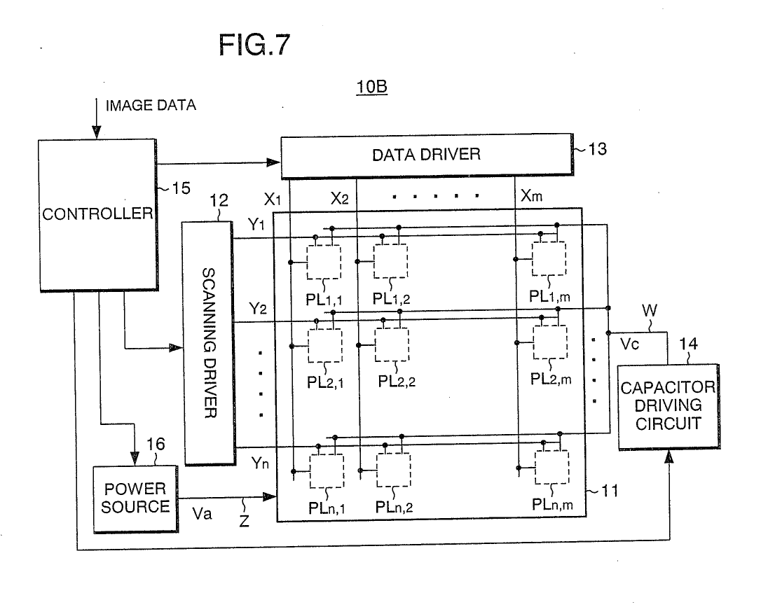

FIG. 7 illustrates a display device or apparatus 10B using an active matrix display panel according to the present invention.

As shown in FIG. 7, in the embodiment, the electrode E2 of the capacitor Cs 24 in each of the pixel portions PL_{1, 1} to PL_{n, m} is connected to the capacitor driving circuit 14 through the capacitor line W. That is, the capacitor line W is connected as a common connection line to the capacitor 24 of all the pixel portions PL_{1, 1} to PL_{n, m} of the display panel 11. Accordingly, the same capacitor driving voltage Vc is applied from the capacitor driving circuit 14 to the respective capacitors 24 of the display panel 11.

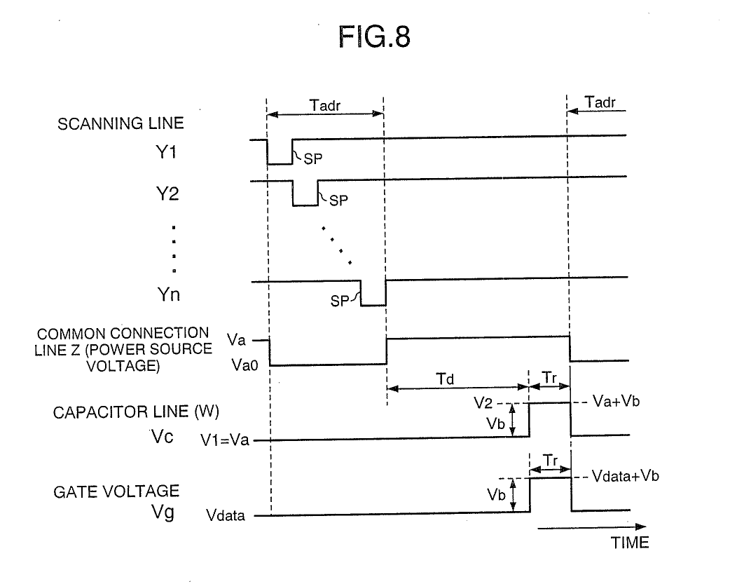

FIG. 8 is a timing chart showing an application timing of scanning pulses applied to scanning lines Y1 to Yn of the display panel 11 and an application timing of the capacitor driving voltage Vc applied to the capacitor line W.

In each frame of an input image signal, scanning pulses SP are sequentially applied to the first to n-th scanning lines Y1 to Yn (addressing period: Tadr) so as to perform line sequential scanning. In more detail, the first capacitor driving voltage V1=Va is applied to the capacitor Cs 24 through the capacitor line W. Similarly to the above-mentioned embodiment, the first capacitor driving voltage V1 may be a predetermined voltage. In the second embodiment, it will be described that a case where the capacitor driving voltage V1 is equal to the light-emitting element driving voltage Va applied to the source of the driving TFT 22 (i.e., V1=Va>0) when the light-emitting element 25 emits light.

In the second embodiment, in the addressing period (data write period) Tadr, a power source voltage applied to the light-emitting elements 25 in the pixels through the power line Z is held at a low voltage (Va0) by which the light-emitting elements 25 do not emit light. As described below, in the embodiment, after writing data, the reverse bias voltage is equally applied to the switching transistors 27 in the pixels after a predetermined period Td so that the light-emitting elements 25 in the pixels simultaneously emit light. After the addressing period is completed, the power source voltage is changed from the low voltage Va0 to a high voltage Va by which the light-emitting element 25 emits light. The change of the power source voltage is controlled by the controller 15 as described above.

A data signal indicating the luminance of each pixel is applied through the data line X1 to Xm while corresponding to the line sequential scanning (not shown), and the image display of the display panel 11 is controlled. In more detail, when the scanning pulses SP are sequentially applied so as to the scanning line Yj to select the scanning line Yj (scanning line Yj is turned on), the selection TFT 21 in the pixel portion PL_{j, i} on the scanning line Yj is turned on, and the pixel data signal (data voltage Vdata) from the data driver 13 is supplied to the gate of the driving TFT 22 through the TFT 21. After the addressing period is completed, the voltage Vc=Va is supplied to the electrode E2 of the capacitor 24, such that electric charges corresponding to the voltage Va−Vdata are accumulated in the capacitor 24. A drain current flows in the driving TFT 22 due to the gate-source voltage Vgs (=Vdata−Vc=Vdata−Va<0). Accordingly, the OEL element 25 emits light in accordance with the pixel data signal (data voltage Vdata).

In the embodiment, after the first to n-th scanning lines Y1 to Yn are scanned (addressing period: Tadr), the capacitor bias voltage Vb (>0) is applied, in addition to the first capacitor driving voltage V1=Va, from the capacitor driving circuit 14 to the electrode E2 of the capacitor 24 through the capacitor line W after a predetermined period Td. That is, in the capacitors 24 in the pixel portions, the capacitor bias voltage Vb is simultaneously applied to the electrodes E2 of the capacitors 24 each of which is not connected to the gate of the driving TFT 22. Thus, the capacitor driving voltage Vc applied to the electrode E2 of the capacitor Cs 24 becomes Vc=V2=Va+Vb.

As the capacitor driving voltage Vc varies, the gate voltage Vg of the driving TFT 22 in each of the pixel portions PL_{j, i} is changed from Vdata to Vdata+Vb. At this time, it is possible to apply the positive reverse bias voltage (Vr=Vdata+Vb−Va>0) between the gate and the source of the driving TFT 22 by setting the gate voltage Vg=Vdata+Vb of the driving TFT 22 to exceed the source voltage Vs=Va of the driving TFT 22 (i.e., Vdata+Vb>Va). Thus, by applying the voltage Vc to the electrode E2 of the capacitor 24, it is possible to apply the positive reverse bias voltage (Vr>0) between the gate and the source of the driving TFT 22, and to reduce the threshold voltage (Vth) shift and the gate stress. The application period Tr of the reverse bias voltage (Vr>0) can be set in an arbitrary manner. Meanwhile, it is possible to reduce the threshold voltage (Vth) shift of TFT by setting the gate voltage Vg=Vdata+Vb of the driving TFT 22 to be equal to the source voltage Vs=Va of the driving TFT 22 (i.e., Vdata+Vb=Va) so that the gate-source voltage is equal to 0V (Vr=0).

### Third Embodiment

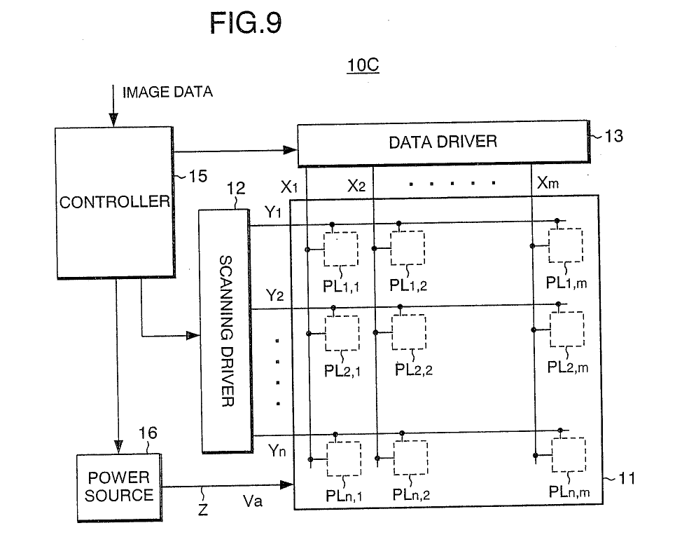

FIG. 9 illustrates a display device 10C using an active matrix display panel according to the invention. The third embodiment is different from the above-mentioned embodiments in that the capacitor driving circuit 14 and the connection line (capacitor line) W1 to Wn connected to the capacitor driving circuit 14 are not provided.

The selection transistor 21 and the driving transistor 22 have conductive types of opposite polarities from each other. In the embodiment, the selection transistor 21 is an N-channel TFT, and the driving transistor 22 is a P-channel TFT. The conductive types of the transistors 21 and 22 are not limited thereto and can be properly selected.

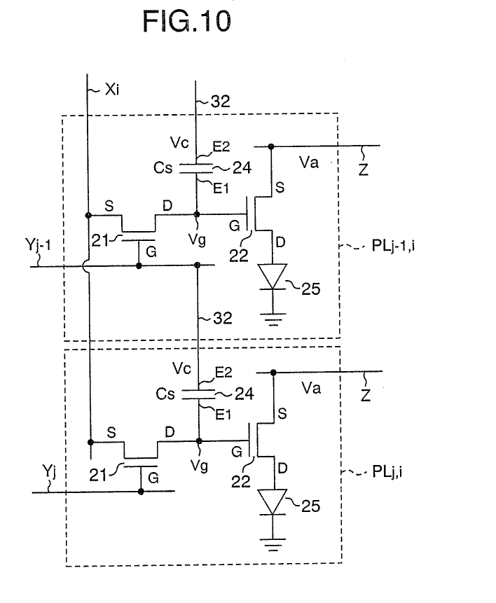

In the embodiment, a scanning pulse voltage applied to the scanning line Yj is used as the capacitor driving voltage Vc. FIG. 10 shows a circuit configuration of pixel portions PL_{j-1, i} and PL_{j, i} in a display panel 11 of the third embodiment. As shown in FIG. 10, in the embodiment, the electrode E2 of the capacitor Cs 24 in the pixel portion PL_{j, i} on the j-th scanning line Yj is connected to a (j−1)-th scanning line Yj−1 (j=2 to n) through the connection line 32. Other circuit configurations and the connections between elements are the same as those of the above-mentioned embodiments.

In the embodiment, each of the electrodes E2 (the second terminal) of the capacitors in the pixel portion PL_{j, i} on the first-row scanning line (j=1) that is first scanned in each display frame are connected to the last-row scanning line (j=n) of the display panel that is last scanned. Other circuit configurations and the connections between elements are the same as those of the above-mentioned embodiments.

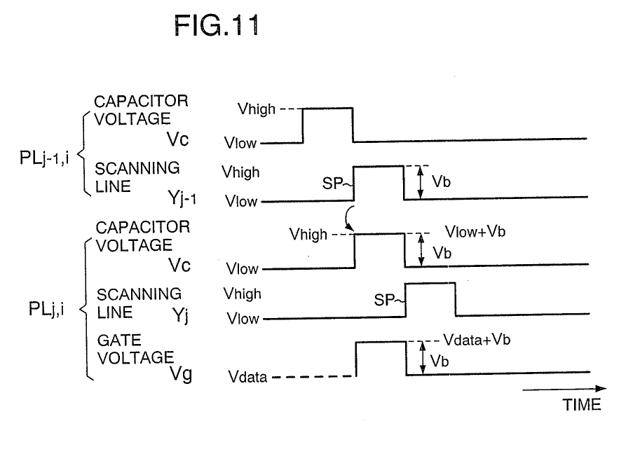

FIG. 11 is a timing chart showing an application timing of scanning pulses applied to scanning lines Yj−1 to Yj of the display panel 11 and an application timing of a capacitor driving voltage Vc applied to capacitors 24 in pixel portions PL_{j-1, i} and PL_{j, i}. Referring to the pixel portion PL_{j, i}, the scanning pulse SP is applied to the scanning line Yj−1 that is one line (i.e., one scan) before the scanning line Yj and, at the same time, to the electrode E2 of the capacitor 24 in the pixel portion PL_{j, i} on the scanning line Yj. Here, the scanning line has a voltage Vlow with a low level, and the scanning pulse SP has a pulse height of the voltage Vb (i.e., the scanning signal is at a high level and has the voltage VHigh=Vlow+Vb). When the corresponding scanning pulse is applied to the electrode E2 of the capacitor 24 in the pixel portion PL_{j, i}, the gate voltage Vg of the driving TFT 22 in the pixel portion PL_{j, i} is changed from the data voltage Vdata held in the capacitor 24 to Vdata+Vb.

Accordingly, in this case, it is possible to apply a positive reverse bias voltage (Vr=Vdata+Vb−Va>0) between the gate and the source of the driving TFT 22 by setting the gate voltage Vg=Vdata+Vb of the driving TFT 22 to exceed the source voltage Vs=Va of the driving TFT 22 (i.e., Vdata+Vb>Va). Similarly to the above-mentioned embodiments, it is possible to reduce the threshold voltage (Vth) shift of TFT by setting the gate voltage Vg=Vdata+Vb of the driving TFT 22 to be equal to the source voltage Vs=Va of the driving TFT 22 and setting the gate-source voltage to 0V (Vr=0). In the third embodiment, it has been described that a case where the electrode E2 of the capacitor 24 in the pixel portion PL_{j, i} on the j-th scanning line Yj is connected to the scanning line Yj−1 that is one scanning line ahead of the scanning line Yj, the invention is not limited thereto. For example, the electrode E2 of the capacitor 24 in the pixel portion PL_{j, i} on the scanning line Yj may be connected to a scanning line Yj+1 that is one scanning line after the scanning line Yj, or may be connected to another scanning line. A connection line (scanning line j=0) for applying the capacitor driving voltage to the electrode E2 of the capacitor in the first-row pixel portion PL_{1, i} may be formed on the display panel 11. In this case, the scanning driver 12 operates to drive (n+1) scanning lines (i.e., j=0 to n). The connection line connected to the electrode E2 of the capacitor in the first-row pixel portion may not be formed, or may not be connected to another scanning line.

As described above, according to the above-mentioned configuration, it is possible to solve a deviation of the threshold characteristic of transistor, thus providing a display device that shows a high display quality and has a low power consumption and simple circuit configuration and operation.

### Fourth Embodiment

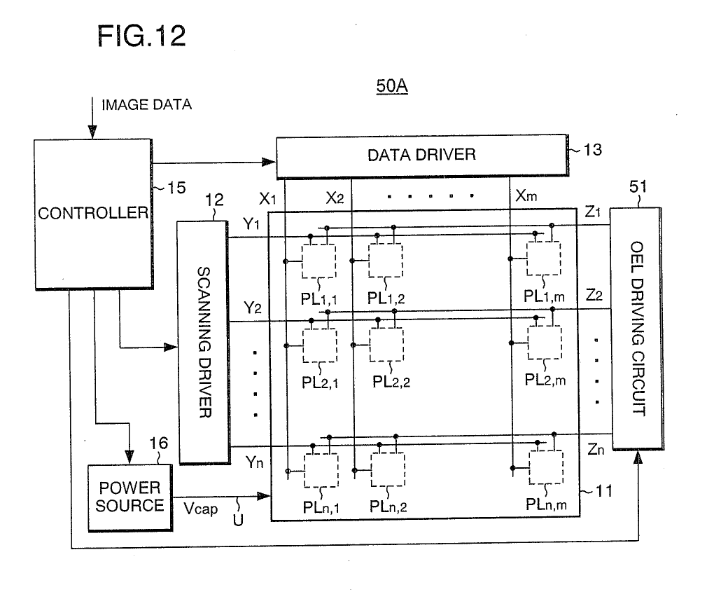

FIG. 12 illustrates a display device 50A having an active matrix display panel according to a fourth embodiment of the present invention. The display device 50A includes a display panel 11, a scanning driver 12, a data driver 13, a light-emitting element driving circuit (OEL driving circuit) 51, a controller 15, and a power source 16. The pixel portions PL_{1, 1} to PL_{n, m} are provided with a capacitor application voltage Vcap from the power source 16 through a capacitor line U. The capacitor application voltage Vcap may be identical to the voltage applied (Va) to the source of the driving TFT when driving the light-emitting (OEL) element 25 to emit light.

The display panel 11 includes connection lines (hereinafter, also referred to as light-emitting element driving lines) Z1 to Zn which are correspondingly provided to the scanning lines Y1 to Yn, respectively. As described below, a reverse bias voltage Vr having a predetermined magnitude is supplied to each of the light-emitting element driving lines Z1 to Zn from the light-emitting element driving circuit 51 in a predetermined timing.

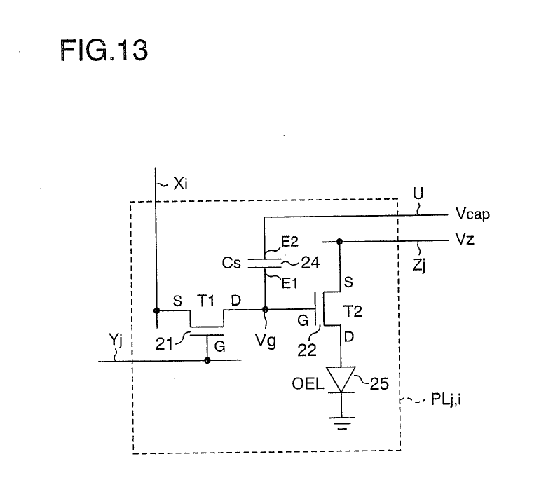

FIG. 13 illustrates a pixel portion PL_{j, i} related to a data line Xi (i=1, 2, . . . , m) and a scanning line Yj (j=1, 2, . . . , n) among a plurality of pixel portions of the display panel 11. The arrangement of the embodiment is different from the above-described embodiments in that the second terminal (electrode E2) of the capacitor Cs 24 is connected to the power source 16 through the capacitor line U, and the source of the driving TFT 22 is connected to the light-emitting element driving circuit 51 through the light-emitting element driving lines Zj (j=1 to n). The source of the TFT 22 is supplied with a driving voltage Vz from the light-emitting element driving circuit 51.

The light-emitting element driving circuit 51 serves as an application voltage generating portion which generates an application voltage (driving voltage Vz) applied to the source of the TFT 22 and a driving voltage adjusting portion which adjusts the application voltage (driving voltage Vz).

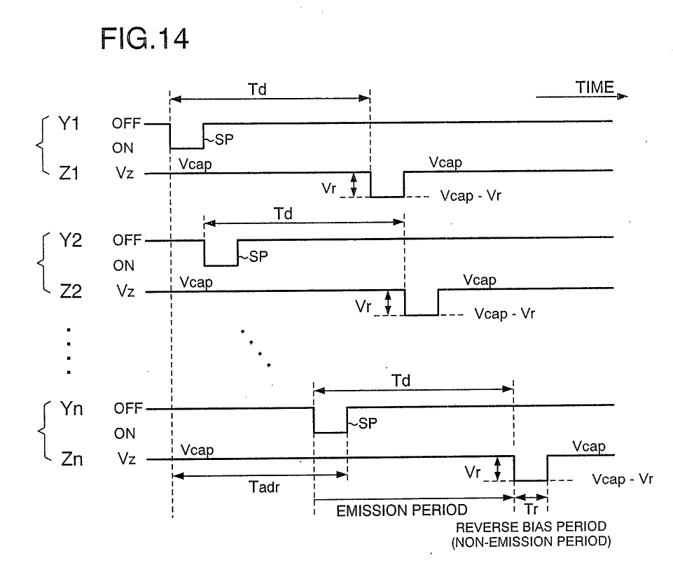

FIG. 14 is a timing, chart showing an application timing of scanning pulses (SP) applied to the scanning lines Y1 to Yn of a display panel 11 and an application timing of the driving voltage Vz applied to the light-emitting element driving lines Z1 to Zn.

The driving voltage Vz is changed after a predetermined time has elapsed from the start timing of the scanning pulse application (i.e., start of data writing) to the scanning lines Yj (j=1 to n). More specifically, the driving voltage Vz is changed from Vcap to Vcap-Vr by applying a reverse bias voltage (magnitude: Vr) to the source of the TFT (T2) 22 through the light-emitting element driving line Zj (j=1 to n) from the light-emitting element driving circuit 51. In the embodiment, the period (Td) from the start of data writing to the change of the driving voltage Vz is set identical for each of the scanning lines, however the period (Td) may be set different for each of the scanning lines.

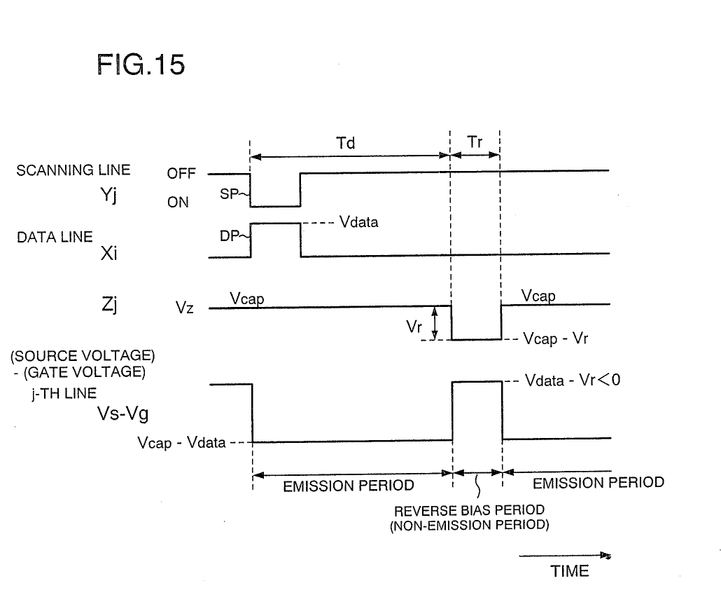

FIG. 15 shows a voltage change of the j-th scanning line Yj, and the driving TFT 22 when the reverse bias voltage is applied. In this example, light emission is started when data writing is started (i.e., start of the light emission period), and light emission is prevented in the period during which the reverse bias voltage is applied to the driving TFT 22 by the change of the driving voltage Vz (non-emission period).

More specifically, the data voltage Vdata of the data signal is written to the capacitor 24 when the scanning signal SP is changed to be ON-state, so that the applied voltage between the source and the gate of the TFT becomes Vcapp−Vdata. Then, as the voltage of the light-emitting element driving line Zj is decreased by Vr (reverse bias voltage), the applied voltage between the source and the gate of the TFT 22 becomes (Vcap−Vr)−(Vcap−Vdata)=Vdata−Vr. The reverse bias voltage can be applied to the driving TFT 22 when the voltage Vr is determined to satisfy the condition Vdata−Vr<0. In other words, the source-gate voltage of the driving TFT 22 is negative (Vdata−Vr<0) during the reverse-bias period.

Further, it is possible to reduce the threshold voltage (Vth) shift of the driving TFT by setting the gate voltage Vg of the TFT 22 to be equal to the source voltage Vs of the driving TFT 22, i.e., by setting the gate-source voltage can be equal to 0V.

The application period of time (Tr) of the reverse bias voltage may be determined in an arbitrary manner.

In the embodiment, the reverse bias voltage can be applied to the driving TFT 22 for each scanning line. Accordingly, in a similar manner to that of the first embodiment, the light-emitting period Td can be controlled for each scanning line. In other words, when the period Td from the application of the scanning pulse SP to the application of the reverse bias voltage is set to be the same for each scanning line, the light-emitting period Td can be equally set for all the scanning lines. In another instance, the light-emitting period may be controlled to be differently set for each scanning line by setting different light-emitting periods (i.e., Td1, Td2, . . . , Tdn) for the scanning lines.

Additionally, a voltage simply for preventing light emission of the light-emitting element 25 may be applied when controlling the light-emitting period.

Accordingly, in a similar manner to that of the first embodiment, it is possible to adjust the luminance of the entire display panel 11 by controlling the light-emitting period. Also, sub-field period may be set and gray scale may be controlled by controlling the light-emitting period. For example, the controller 15 determines the light-emitting period Td corresponding to the luminance of the display panel 11 based on an input image signal or the luminance specifying signal of a user to control the application timing of the reverse bias voltage. Meanwhile, a desired sub-field period can be determined to control the gray scale, when the display control is performed by a sub-field method.

In addition, while an instance where the period Td is larger than the addressing period (Tadr<Td) has been described, the period Td may be set to be shorter than the addressing period (Tadr>Td or Tadr=Td). Also, the application period Tr of the reverse bias voltage may be arbitrary set with respect to each scanning line.

Thus, it is possible to apply reverse bias voltage between the gate and the source (i.e., between the control electrode and the other electrode) of the driving TFT 22 by changing the source voltage (driving voltage Vz) of the TFT 22, so that the threshold voltage (Vth) shift of the driving TFT 22 is reduced and the gate stress is reduced.

### Fifth Embodiment

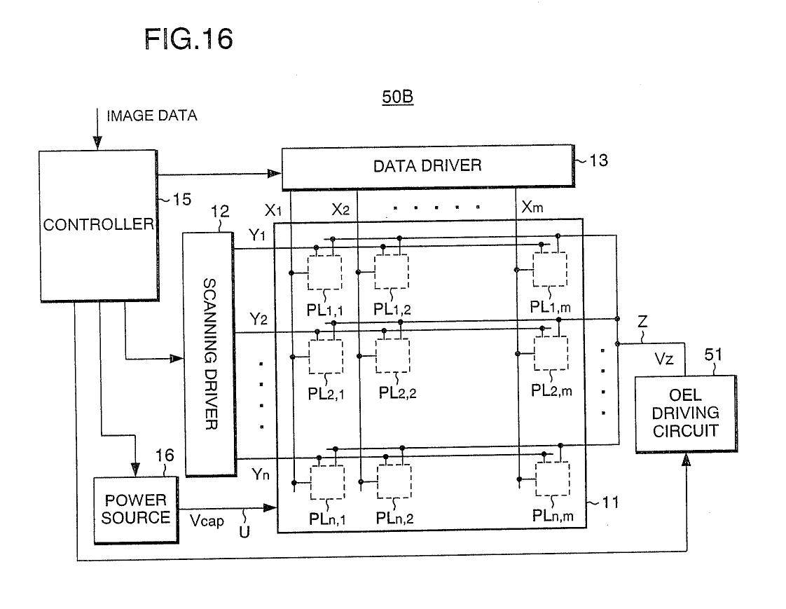

FIG. 16 illustrates a display device 50B having an active matrix display panel according to a fifth embodiment of the present invention.

As shown in FIG. 16, in the embodiment, the source of the driving TFT 22 in each of the pixel portions PL_{1, 1} to PL_{n, m} is connected to the light-emitting element driving circuit (OEL driving circuit) 51 through the light-emitting element driving line Z. That is, the light-emitting element driving line Z is connected as a connection line common to the sources of the driving TFTs 22 of all the pixel portions PL_{1, 1} to PL_{n, m}. The sources of all the driving TFTs 22 of the display panel 11 is supplied with the driving voltage Vz from the light-emitting element driving circuit 51.

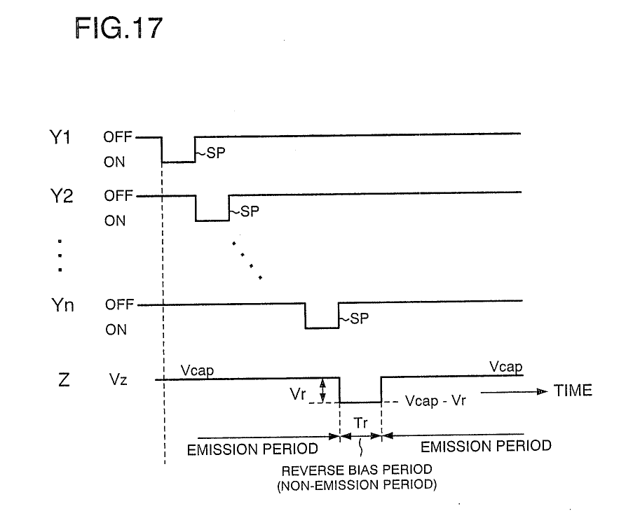

FIG. 17 is a timing chart showing an application timing of scanning pulses (SP) applied to scanning lines Y1 to Yn of the display panel 11 and an application timing of the driving voltage Vz applied to the light-emitting element driving line Z.

As shown in FIG. 17, the driving voltage Vz is changed after data writing is performed for all of the scanning lines to apply reverse bias voltage to the TFT 22 during a predetermined period (the reverse-bias period Tr). More specifically, the application voltage to the light-emitting element driving line Z is changed from Vcap to Vcap−Vr and the application voltage is Vcap-Vr during the reverse-bias period Tr.

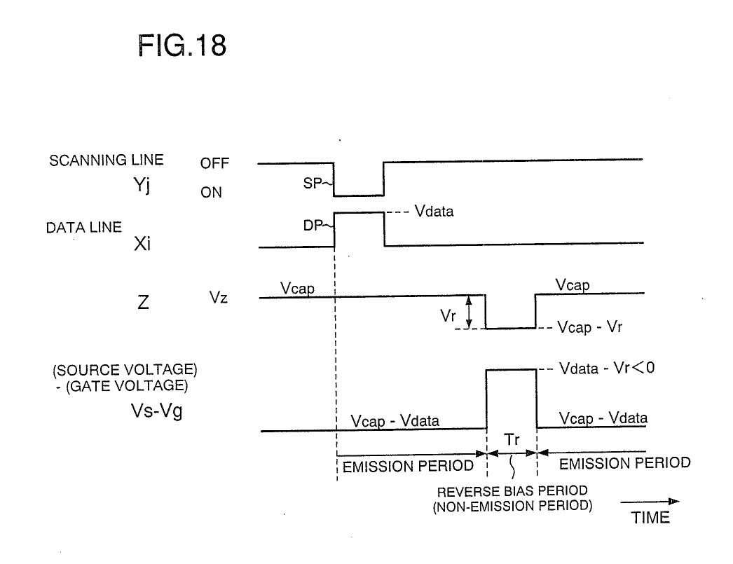

FIG. 18 shows voltage change of the j-th scanning line Yj, and the driving TFT 22 when the reverse bias voltage is applied. In this example, light emission is started when data writing is started (start of the light emission period), and light emission is stopped in the period during which the reverse bias voltage is applied to the driving TFT 22 by the change of the driving voltage Vz (non-emission period). In other words, the source-gate voltage of the driving TFT 22 is negative (Vdata−Vr<0) during the reverse-bias period.

Thus, it is possible to apply a reverse bias voltage between the gate and the source of the driving TFT 22 by changing the source voltage (driving voltage Vz) of the TFT 22.

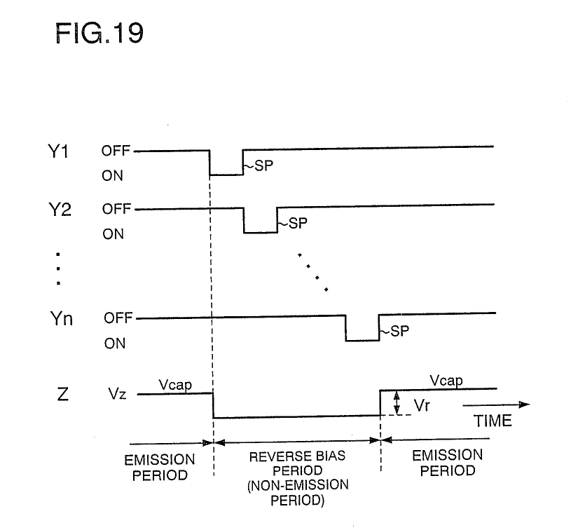

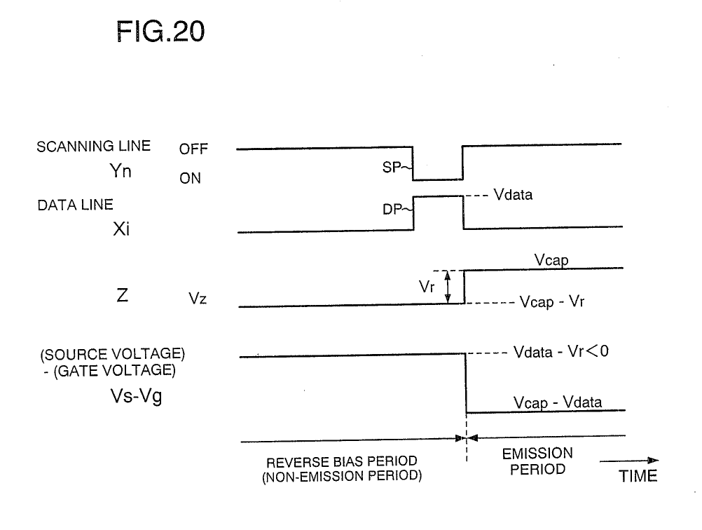

FIGS. 19 and 20 illustrate timing charts of the modifications of the embodiment. As shown in FIG. 19, the reverse bias voltage is applied to the TFTs 22 over the period of time to write data to the pixels for all the scanning lines (i.e., addressing period). As shown in FIG. 20, the source-gate voltages of all the TFTs 22 are negative (Vdata−Vr<0) during the reverse-bias application period.

### Sixth Embodiment

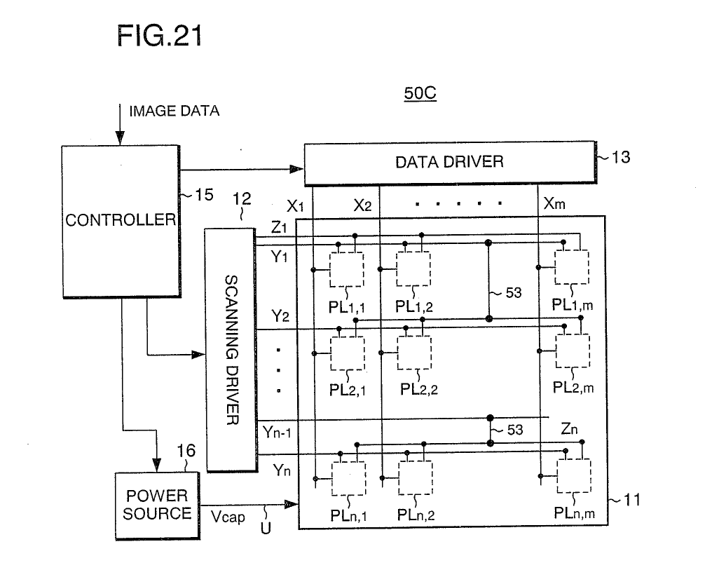

FIG. 21 illustrates a display device 50C having an active matrix display panel according to a sixth embodiment of the present invention.

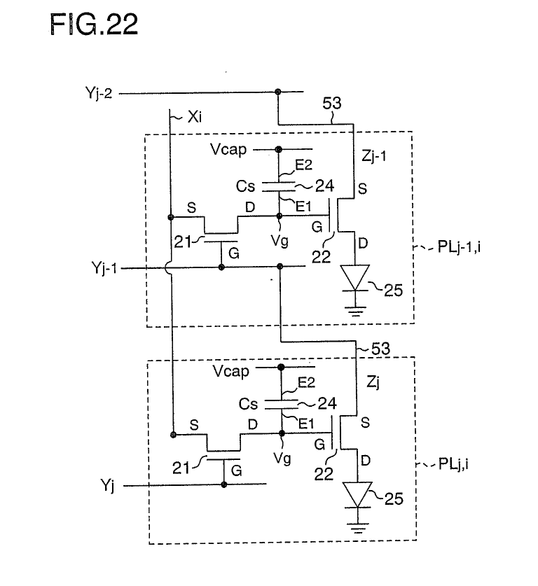

In the embodiment, a scanning pulse voltage applied to the scanning line Yj is used as the driving voltage Vz. FIG. 22 shows a circuit configuration of pixel PL_{j-1, i} and PL_{j, i} in a display panel 11 of the embodiment. As shown in FIG. 22, in the embodiment, the source of the driving TFT 22 in the pixel portion PL_{j, i} on the j-th scanning line Yj is connected to a (j−1)-th scanning line Yj−1 (j=2 to n) that is one line (i.e., one scan) before the scanning line Yj through a connection line (Zj) 53. Other circuit configurations and the connections between elements are the same as those of the above-mentioned embodiments.

In the embodiment, each of the sources of the driving TFTs 22 in the pixel portion PL_{j, i} on the first-row scanning line (j=1) that is first scanned in each display frame are connected to the last-row scanning line (j=n) of the display panel that is last scanned. Other circuit configurations and the connections between elements are the same as those of the above-mentioned embodiments.

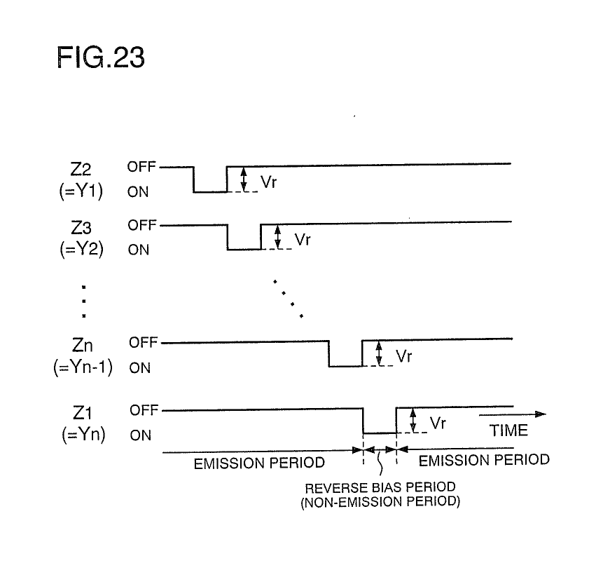

FIG. 23 is a timing chart illustrating the voltage applied to the scanning line Yj as well as the voltage applied to the connection line (Zj) 53 (j=1 to n). The voltage Vcap is applied to the scanning line Yj when the scanning line Yj is not selected, while the voltage Vcap−Vr is applied to the scanning line Yj when the scanning line Yj is selected. The voltage applied to the (j−1)-th scanning line Yj−1 that is one line scanned before the scanning line Yj is applied to the sources of the driving TFTs 22 in the pixel portions PL_{j, i} on the scanning line Yj.

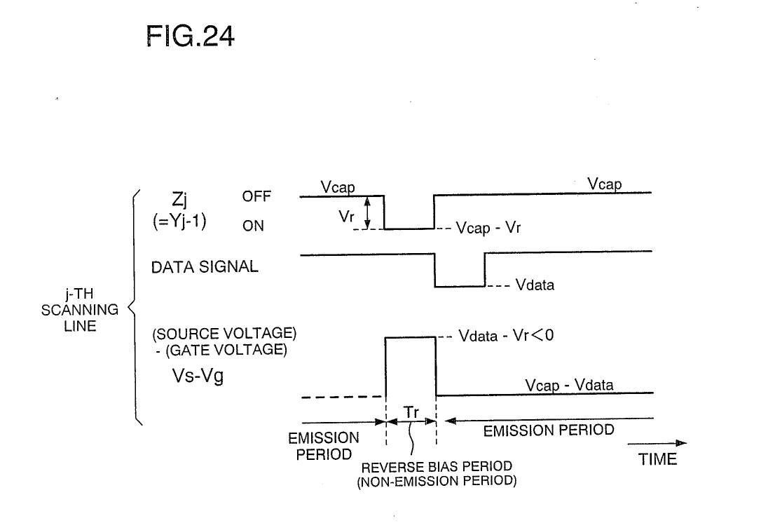

FIG. 24 illustrates the scanning voltage applied to the source of the TFT 22 in the pixel portions PL_{j, i} on the scanning line Yj, together with the data voltage to the TFT 22 and the source-gate voltage of the TFT 22. When the (j−1)-th scanning line Yj−1 is selected, the voltage applied to the (j−1)-th scanning line Yj−1 that is one line scanned before the scanning line Yj is applied to the source of the driving TFT 22 on the scanning line Yj through the connection line (Zj) 53, so that the [(source voltage)−(gate voltage)] becomes Vdata−Vr (<0) and the reverse bias voltage is applied to the driving TFT 22.

In the next scan, the scanning line Yj is selected and the data signal (data voltage Vdata) is supplied, so that the [(source voltage)−(gate voltage)] of the driving TFT 22 on the scanning line Yj changes to (Vcap−Vdata) and transfers into an emission state or mode.

In the embodiment, it has been described for an instance when the sources of the TFTs 22 in the first-row (j=1) pixel portion PL_{1, i} are connected to the last scanning line Yn (i.e., j=n), the invention is not limited thereto. For example, the scanning driver 12 may be configured to supply the reverse bias voltage to the sources of the TFTs 22 in the first scanning line Y₁ (i.e., j=1).

### Seventh Embodiment

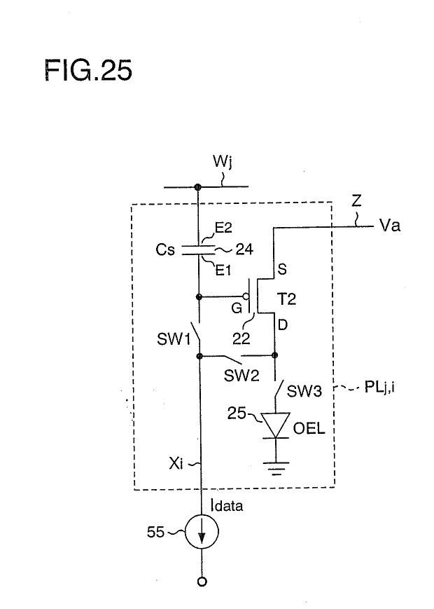

FIG. 25 illustrates a pixel portion of a seventh embodiment of the present invention, specifically, a pixel portion PL_{j, i} related to a data line Xi (i=1, 2, . . . , m) and a scanning line Yj (j=1, 2, . . . , n) among a plurality of pixel portions of the display panel 11. The seventh embodiment has an arrangement or configuration in which the above-described first embodiment is modified to be suitable or adapted to a current program method.

In more detail, there are provided, in the pixel portion PL_{j, i}, a driving TFT (T2) 22, a data holding capacitor Cs 24, a light-emitting element (e.g., OEL) 25, a constant current source 55 and switches SW1-SW3. The switches SW1-SW3 are configured by transistors. Specifically, the embodiment has a configuration adapted to a four-transistor current program method. In the embodiment, the data driver 13 is configured to be a constant-current source driver, and a data current Idata is supplied to the pixel portion PL_{j, i} from a constant current source 55 of the data driver 13, the current source 55 corresponding to the data line Xi. The other configuration is similar to that of the first embodiment (see, FIG. 3). The second electrode E2 of the capacitor Cs is connected to the capacitor driving circuit 14 through the capacitor line Wj (j=1 to n). In a similar manner to the first embodiment, a predetermined voltage (i.e., light-emitting element driving voltage) Va is supplied to the source of the driving TFT (T2) 22 via a power source line Z from the power source 16. Further, also similar to the first embodiment, connection lines (capacitor lines) W1 to Wn are provided which are corresponding to the scanning lines Y1 to Yn, respectively (see FIG. 3).

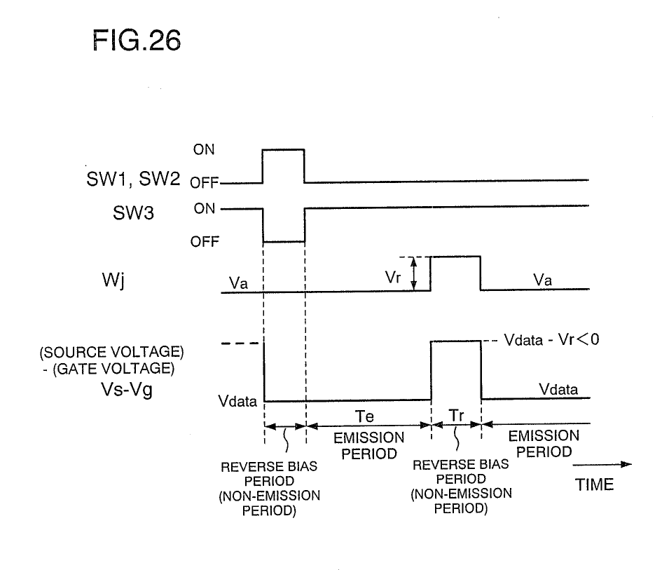

As shown in FIG. 26, in a write period (or write mode), the switches SW1 and SW2 are closed (ON state) and the switch SW3 is open (OFF state). The voltage Vcap (=Va) is applied to the capacitor line Wj. In the next step, the switch SW3 is closed (ON state) and the switches SW1 and SW2 are open (OFF state) so that light emission of the light-emitting element (e.g., OEL) 25 is initiated.

Then, a reverse bias voltage Vr is applied to the capacitor line Wj after a predetermined period (light-emission period Te) has elapsed, so that the [(source voltage)−(gate voltage)] of the driving TFT 22 changes to Vdata−Vr (<0) and the reverse bias is applied to the driving TFT 22 (reverse bias period or non-emission period: Tr).

In the embodiment, description is made for a display apparatus in which the application voltage to the second electrode E2 of the capacitor 24 is changed so as to apply a reverse bias voltage to the driving TFT 22. In a modified embodiment, connection lines (light-emitting element driving lines) Z1 to Zn which are correspondingly provided to the scanning lines Y1 to Yn are provided, and the application voltage to the source of the driving TFT 22 can be changed in a similar manner to the fourth embodiment (see FIG. 12), instead of changing the application voltage to the second electrode E2 of the capacitor 24.

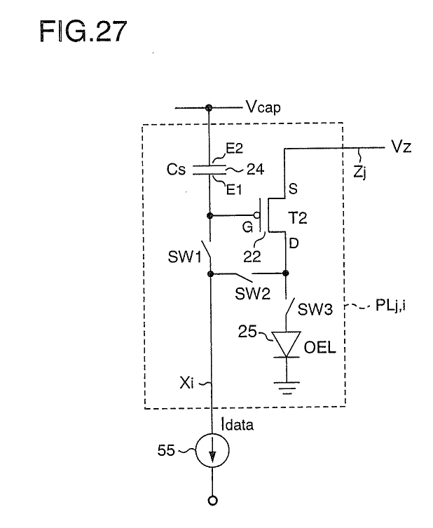

FIG. 27 shows the configuration of the pixel PL_{j, i} of the modified embodiment, and the modified embodiment is similar to the sixth embodiment (FIG. 25) in that the configuration of the modified embodiment is adapted to the four-transistor current program method.

For example, in a similar manner to the fourth embodiment (FIG. 12), a fixed voltage (Vcap:constant) is applied to the second electrode E2 of the capacitor 24, and the connection line (light-emitting element driving line) Zj is connected to the light-emitting element driving circuit 51 so as to be able to change the application voltage to the source of the driving TFT 22 for each of the scanning lines Y1-Yn. The other arrangements or configuration is similar to that of the fourth embodiment (FIG. 12).

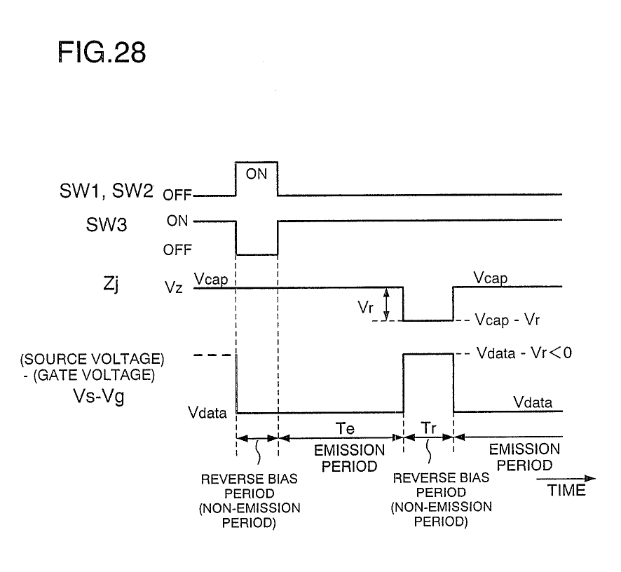

As shown in FIG. 28, in a write period (or write mode), the switches SW1 and SW2 are closed (ON state) and the switch SW3 is open (OFF state). The voltage Vcap is applied to the light-emitting element driving line Zj. In the next step, the switch SW3 is closed (ON state) and the switches SW1 and SW2 are open (OFF state) so that light emission of the light-emitting element (e.g., OEL) 25 is initiated.

Then, a reverse bias voltage Vr is applied to the light-emitting element driving line Zj after a predetermined period (light-emission period Te) has elapsed, so that the [(source voltage)−(gate voltage)] of the driving TFT 22 changes to Vdata−Vr (<0) and the reverse bias is applied to the driving TFT 22 (reverse bias period or non-emission period: Tr).

It should be understood that the embodiment is described in the context that the four-transistor current program method is used, however, the present invention can be adapted to voltage program method.

As described above, according to the present invention, it is possible to solve a deviation of the threshold characteristic of transistor, thus providing a display device that shows a high display quality and has a low power consumption and simple circuit configuration and operation.

It should be understood that the above-described embodiments can be modified as necessary or can be adapted in a combined manner. In the embodiments, the type of transistor, polarities of the transistors and voltages, magnitudes of the voltages are exemplary. For example, the polarities of the TFT 21 and 22 can be arbitrary selected. More specifically, the selection and driving TFTs may be any one of p-channel and n-channel transistors, and the polarity and the magnitude of the voltage, for example, applied to the gate electrode (control electrode) can be designed. Additionally, in the embodiments, description has been made for a case in which the application voltage to the source of the driving TFT is changed to apply a reverse voltage. However, the application voltage to the drain of the driving TFT may be changed, instead of changing the application voltage to the gate of the driving TFT. In other words, the polarity, the magnitude and the like of the elements or transistors can be selected according to the elements or transistors used.

What is claimed is:

1. A display apparatus comprising:
an active matrix display panel which includes a plurality of pixel portions each having a light-emitting element and a driving transistor for driving the light-emitting element based on a data signal;
a scanning driver unit which sequentially scans scanning lines of the display panel;
a data driver unit which supplies the data signal to the pixel portions in accordance with the scanning of the scanning driver unit;
a capacitor which is provided in each of the pixel portions to be connected to the driving transistor and stores the data signal;
common connection lines which are provided correspondingly to the scanning lines, each common connection line being connected to second electrodes of the driving transistors in pixel portions on a corresponding scanning line, and the second electrodes being different from control electrodes of the driving transistors;
an application voltage generating unit which generates an application voltage to each of the common connection lines; and
a driving voltage adjusting unit which adjusts the application voltage to the common connection lines.

2. The display apparatus according to claim 1, wherein the driving voltage adjusting unit adjusts the application voltage to the common connection lines so as to apply a reverse bias voltage to the driving transistors.

3. The display apparatus according to claim 1, wherein the driving voltage adjusting unit adjusts the application voltage to the common connection lines so as to control a light-emitting time period of the light-emitting element.

4. The display apparatus according to claim 3, wherein;
the driving voltage adjusting unit adjusts the light-emitting time period of the light emitting element every time the scanning driver unit scans.

5. The display apparatus according to claim 3,
wherein the scanning driver unit scans the display panel on based on a sub-field method, and
the driving voltage adjusting unit controls the light-emitting time period of the light emitting element in accordance with a length of a sub-field period.

6. The display apparatus according to claim 3,
wherein the driving voltage adjusting unit controls the light-emitting time period of the light-emitting elements in accordance with a luminance of the display panel based on an input image signal or a luminance specifying signal of a user.
